(19) United States
(12) Patent Application Publication
(10) Pub. No.: US 2025/0355181 A1
(43) Pub. Date: Nov. 20, 2025

(54) OPTICAL DEVICE AND METHOD OF MANUFACTURE

(71) Applicant: Taiwan Semiconductor Manufacturing Co., Ltd., Hsinchu (TW)

(72) Inventors: Chia-Han Tsou, Hsinchu (TW); Ming-Fa Chen, Taichung City (TW)

(21) Appl. No.: 19/279,771

(22) Filed: Jul. 24, 2025

Related U.S. Application Data
(63) Continuation of application No. 18/891,076, filed on Sep. 20, 2024.
(60) Provisional application No. 63/638,165, filed on Apr. 24, 2024.
(60) Provisional application No. 63/654,374, filed on May 31, 2024.

(51) Int. Cl. G02B 6/13; H01L 23/00; H01L 25/16; H10F 77/40

(52) U.S. Cl. CPC G02B 6/13; H01L 25/167; H10F 77/407; H01L 24/08; H01L 24/80; H01L 2224/08145; H01L 2224/80895; H01L 2224/80896

(57) ABSTRACT

Optical devices and methods of manufacture are presented in which a protective layer is formed over a support substrate, a first semiconductor die, and an optical interposer. The optical interposer is encapsulated with an encapsulant with a second semiconductor die. The encapsulant is planarized with the second semiconductor die, and the encapsulant is removed to expose the protective layer after the planarizing the encapsulant.

### PRIORITY CLAIM AND CROSS-REFERENCE

This application is a continuation of U.S. patent application Ser. No. 18/891,076, filed Sep. 20, 2024, which application claims the benefit of U.S. Provisional Application No. 63/638,165, filed on Apr. 24, 2024, and U.S. Provisional Application No. 63/654,374, filed on May 31, 2024, which applications are hereby incorporated herein by reference.

### BACKGROUND

Electrical signaling and processing is one technique for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating long-range optical components and short-range electrical components are formed for the conversion between optical signals and electrical signals, as well as the processing of optical signals and electrical signals. Packages thus may include both optical (photonic) dies including optical devices and electronic dies including electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 illustrate steps in a formation of a first optical package, in accordance with some embodiments.

FIGS. 7A-7E illustrate an attachment of a support substrate with a protection layer, in accordance with some embodiments.

FIGS. 8-9 illustrate additional steps in the formation of the first optical package, in accordance with some embodiments.

FIG. 10 illustrates an interposer substrate, in accordance with some embodiments.

FIG. 11 illustrates a bonding of the first optical package to the interposer substrate, in accordance with some embodiments.

FIG. 12 illustrates a thinning of an encapsulant, in accordance with some embodiments.

FIG. 13 illustrates a removal of the encapsulant, in accordance with some embodiments.

FIG. 14 illustrates a bonding of the interposer substrate to a second substrate, in accordance with some embodiments.

FIG. 15 illustrates a placement of a fiber array unit, in accordance with some embodiments.

FIG. 16 illustrates placement of a heat sink, in accordance with some embodiments.

FIG. 17 illustrates usage of a second anti-reflective coating, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be discussed with respect to certain embodiments in which a protective layer is utilized over a first optical package in order to help form a more planar surface to receive and transmit optical signals. The embodiments presented, however, are intended to be illustrative and are not intended to limit the ideas presented to the precise embodiments described. Rather, the ideas presented may be incorporated into a wide variety of embodiments, and all such embodiments may be included within the overall scope of the disclosure.

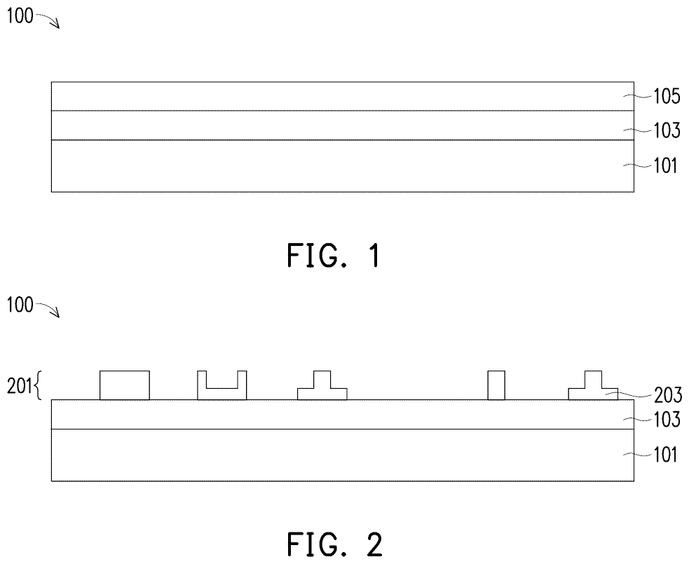

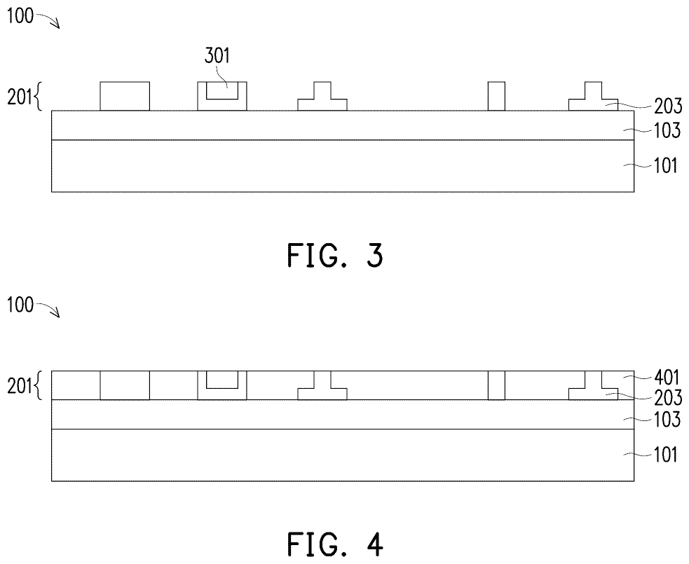

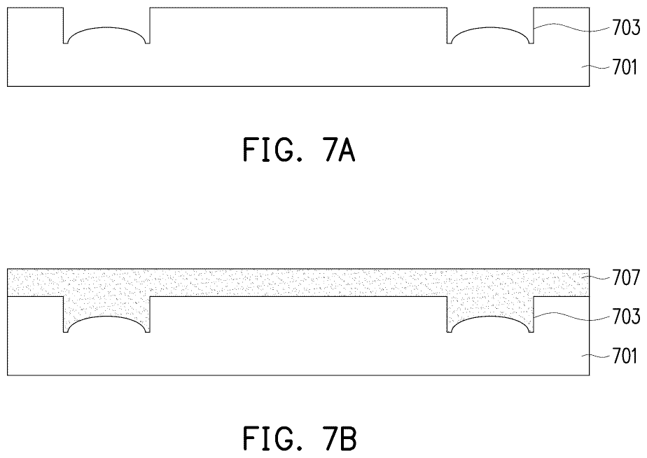

With reference now to FIG. 1, there is illustrated an initial structure of an optical interposer 100 (seen in FIG. 5), in accordance with some embodiments. In the particular embodiment illustrated in FIG. 1, the optical interposer 100 is a photonic integrated circuit (PIC) and comprises at this stage a first substrate 101, a first insulator layer 103, and a layer of material 105 for a first active layer 201 of first optical components 203 (not separately illustrated in FIG. 1 but illustrated and discussed further below with respect to FIG. 2). In an embodiment, at a beginning of the manufacturing process of the optical interposer 100, the first substrate 101, the first insulator layer 103, and the layer of material 105 for the first active layer 201 of first optical components 203 may collectively be part of a silicon-on-insulator (SOI) substrate. Looking first at the first substrate 101, the first substrate 101 may be a semiconductor material such as silicon or germanium, a dielectric material such as glass, or any other suitable material that allows for structural support of overlying devices.

The first insulator layer 103 may be a dielectric layer that separates the first substrate 101 from the overlying first active layer 201 and can additionally, in some embodiments, serve as a portion of cladding material that surrounds the subsequently manufactured first optical components 203 (discussed further below). In an embodiment the first insulator layer 103 may be silicon oxide, silicon nitride, germanium oxide, germanium nitride, combinations of these, or the like, formed using a method such as implantation (e.g., to form a buried oxide (BOX) layer) or else may be deposited onto the first substrate 101 using a deposition method such as chemical vapor deposition, atomic layer deposition, physical vapor deposition, combinations of these, or the like. However, any suitable material and method of manufacture may be used.

The material 105 for the first active layer 201 is initially (prior to patterning) a conformal layer of material that will be used to begin manufacturing the first active layer 201 of the first optical components 203. In an embodiment the material 105 for the first active layer 201 may be a translucent material that can be used as a core material for the desired first optical components 203, such as a semiconductor material such as silicon, germanium, silicon germanium, combinations of these, or the like, while in other embodiments the material 105 for the first active layer 201 may be a dielectric material such as silicon nitride or the like, although in other embodiments the material 105 for the first active layer 201 may be III-V materials, lithium niobate materials, or polymers. In embodiments in which the material 105 of the first active layer 201 is deposited, the material 105 for the first active layer 201 may be deposited using a method such as epitaxial growth, chemical vapor deposition, atomic layer deposition, physical vapor deposition, combinations of these, or the like. In other embodiments in which the first insulator layer 103 is formed using an implantation method, the material 105 of the first active layer 201 may initially be part of the first substrate 101 prior to the implantation process to form the first insulation layer 103. However, any suitable materials and methods of manufacture may be utilized to form the material 105 of the first active layer 201.

FIG. 2 illustrates that, once the material 105 for the first active layer 201 is ready, the first optical components 203 for the first active layer 201 are manufactured using the material 105 for the first active layer 201. In embodiments the first optical components 203 of the first active layer 201 may include such components as optical waveguides (e.g., ridge waveguides, rib waveguides, buried channel waveguides, diffused waveguides, etc.), couplers (e.g., grating couplers, edge couplers that are a narrowed waveguide with a width of between about 1 nm and about 200 nm, etc.), directional couplers, optical modulators (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. However, any suitable first optical components 203 may be used.

To begin forming the first active layer 201 of first optical components 203 from the initial material, the material 105 for the first active layer 201 may be patterned into the desired shapes for the first active layer 201 of first optical components 203. In an embodiment the material 105 for the first active layer 201 may be patterned using, e.g., one or more photolithographic masking and etching processes. However, any suitable method of patterning the material 105 for the first active layer 201 may be utilized. For some of the first optical components 203, such as waveguides or edge couplers, the patterning process may be all or at least most of the manufacturing processes that is used to form these first optical components 203 components.

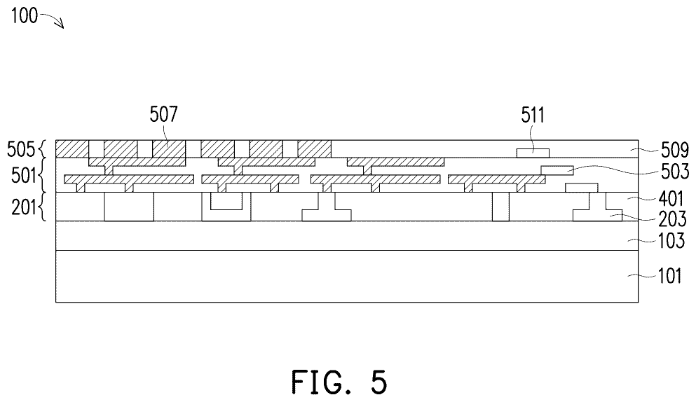

FIG. 3 illustrates that, for those components that utilize further manufacturing processes, such as Mach-Zehnder silicon-photonic switches that utilize resistive heating elements, additional processing may be performed either before or after the patterning of the material for the first active layer 201. For example, implantation processes, additional deposition and patterning processes for different materials (e.g., resistive heating elements, III-V materials for converters), combinations of all of these processes, or the like, can be utilized to help further the manufacturing of the various desired first optical components 203. In a particular embodiment, and as specifically illustrated in FIG. 3, in some embodiments an epitaxial deposition of a semiconductor material 301 such as germanium (used, e.g., for electricity/optics signal modulation and transversion) may be performed on a patterned portion of the material 105 of the first active layer 201. In such an embodiment the semiconductor material 301 may be epitaxially grown in order to help manufacture, e.g., a photodiode for an optical-to-electrical converter. All such manufacturing processes and all suitable first optical components 203 may be manufactured, and all such combinations are fully intended to be included within the scope of the embodiments.

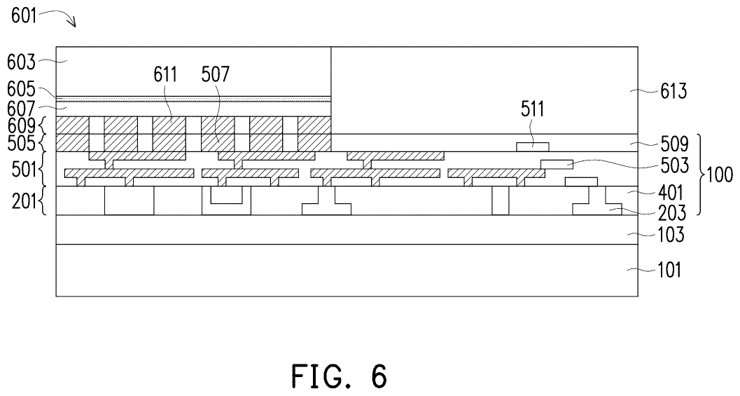

FIG. 4 illustrates that, once the individual first optical components 203 of the first active layer 201 have been formed, a second insulator layer 401 may be deposited to cover the first optical components 203 and provide additional cladding material. In an embodiment the second insulator layer 401 may be a dielectric layer that separates the individual components of the first active layer 201 from each other and from the overlying structures and can additionally serve as another portion of cladding material that surrounds the first optical components 203. In an embodiment the second insulator layer 401 may be silicon oxide, silicon nitride, germanium oxide, germanium nitride, combinations of these, or the like, formed using a deposition method such as chemical vapor deposition, atomic layer deposition, physical vapor deposition, combinations of these, or the like. Once the material of the second insulator layer 401 has been deposited, the material may be planarized using, e.g., a chemical mechanical polishing process in order to either planarize a top surface of the second insulator layer 401 (in embodiments in which the second insulator layer 401 is intended to fully cover the first optical components 203) or else planarize the second insulator layer 401 with top surfaces of the first optical components 203. However, any suitable material and method of manufacture may be used.

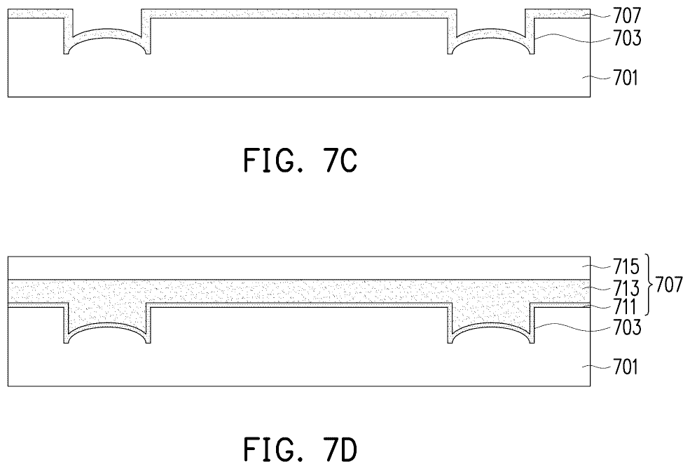

FIG. 5 illustrates that, once the first optical components 203 of the first active layer 201 have been manufactured and the second insulator layer 401 has been formed, first metallization layers 501 are formed in order to electrically connect the first active layer 201 of first optical components 203 to control circuitry, to each other, and to subsequently attached devices (not illustrated in FIG. 5 but illustrated and described further below with respect to FIG. 6). In an embodiment the first metallization layers 501 are formed of alternating layers of dielectric and conductive material and may be formed through any suitable processes (such as deposition, damascene, dual damascene, etc.). In particular embodiments there may be multiple layers of metallization used to interconnect the various first optical components 203, but the precise number of first metallization layers 501 is dependent upon the design of the optical interposer 100.

Additionally, during the manufacture of the first metallization layers 501, one or more second optical components 503 may be formed as part of the first metallization layers 501. In some embodiments the second optical components 503 of the first metallization layers 501 may include such components as couplers (e.g., edge couplers, grating couplers, etc.) for connection to outside signals, optical waveguides (e.g., ridge waveguides, rib waveguides, buried channel waveguides, diffused waveguides, etc.), optical modulators (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. However, any suitable optical components may be used for the one or more second optical components 503.

In an embodiment the one or more second optical components 503 may be formed by initially depositing a material for the one or more second optical components 503. In an embodiment the material for the one or more second optical components 503 may be a dielectric material such as silicon nitride, silicon oxide, combinations of these, or the like, or a semiconductor material such as silicon, deposited using a deposition method such as chemical vapor deposition, atomic layer deposition, physical vapor deposition, combinations of these, or the like. However, any suitable material and any suitable method of deposition may be utilized.

Once the material for the one or more second optical components 503 has been deposited or otherwise formed, the material may be patterned into the desired shapes for the one or more second optical components 503. In an embodiment the material of the one or more second optical components 503 may be patterned using, e.g., one or more photolithographic masking and etching processes. However, any suitable method of patterning the material for the one or more second optical components 503 may be utilized.

For some of the one or more second optical components 503, such as waveguides or edge couplers, the patterning process may be all or at least most of the manufacturing processes that is used to form these components. Additionally, for those components that utilize further manufacturing processes, such as Mach-Zehnder silicon-photonic switches that utilize resistive heating elements, additional processing may be performed either before or after the patterning of the material for the one or more second optical components 503. For example, implantation processes, additional deposition and patterning processes for different materials, combinations of all of these processes, or the like, and can be utilized to help further the manufacturing of the various desired one or more second optical components 503. All such manufacturing processes and all suitable one or more second optical components 503 may be manufactured, and all such combinations are fully intended to be included within the scope of the embodiments.

Once the one or more second optical components 503 of the first metallization layers 501 have been manufactured, a first bonding layer 505 is formed over the first metallization layers 501. In an embodiment, the first bonding layer 505 may be used for a dielectric-to-dielectric and metal-to-metal bond. In accordance with some embodiments, the first bonding layer 505 is formed of a first dielectric material 509 such as silicon oxide, silicon nitride, or the like. The first dielectric material 509 may be deposited using any suitable method, such as CVD, high-density plasma chemical vapor deposition (HDPCVD), PVD, atomic layer deposition (ALD), or the like. However, any suitable materials and deposition processes may be utilized.

Once the first dielectric material 509 has been formed, first openings in the first dielectric material 509 are formed to expose conductive portions of the underlying layers in preparation to form first bond pads 507 within the first bonding layer 505. Once the first openings have been formed within the first dielectric material 509, the first openings may be filled with a seed layer and a plate metal to form the first bond pads 507 within the first dielectric material 509. The seed layer may be blanket deposited over top surfaces of the first dielectric material 509 and the exposed conductive portions of the underlying layers and sidewalls of the openings. The seed layer may comprise a copper layer. The seed layer may be deposited using processes such as sputtering, evaporation, or plasma-enhanced chemical vapor deposition (PECVD), or the like, depending upon the desired materials. The plate metal may be deposited over the seed layer through a plating process such as electrical or electro-less plating. The plate metal may comprise copper, a copper alloy, or the like. The plate metal may be a fill material. A barrier layer (not separately illustrated) may be blanket deposited over top surfaces of the first dielectric material 509 and sidewalls of the openings before the seed layer. The barrier layer may comprise titanium, titanium nitride, tantalum, tantalum nitride, or the like.

Following the filling of the first openings, a planarization process, such as a CMP, is performed to remove excess portions of the seed layer and the plate metal, forming the first bond pads 507 within the first bonding layer 505. In some embodiments a bond pad via (not separately illustrated) may also be utilized to connect the first bond pads 507 with underlying conductive portions and, through the underlying conductive portions, connect the first bond pads 507 with the first metallization layers 501.

Additionally, the first bonding layer 505 may also include one or more third optical components 511 incorporated within the first bonding layer 505. In such an embodiment, prior to the deposition of the first dielectric material 509, the one or more third optical components 511 may be manufactured using similar methods and similar materials as the one or more second optical components 503 (described above), such as by being waveguides and other structures formed at least in part through a deposition and patterning process. However, any suitable structures, materials and any suitable methods of manufacture may be utilized.

FIG. 6 illustrates a bonding of a first semiconductor device 601 to the first bonding layer 505 of the optical interposer 100. In some embodiments, the first semiconductor device 601 is an electronic integrated circuit (EIC—e.g., a device without optical devices) and may have a semiconductor substrate 603, a layer of active devices 605, an overlying interconnect structure 607, a second bonding layer 609, and associated third bond pads 611. In an embodiment the semiconductor substrate 603 may be similar to the first substrate 101 (e.g., a semiconductor material such as silicon or silicon germanium), the active devices 605 may be transistors, capacitors, resistors, and the like formed over the semiconductor substrate 603, the interconnect structure 607 may be similar to the first metallization layers 501 (without optical components), the second bonding layer 609 may be similar to the first bonding layer 505, and the third bond pads 611 may be similar to the first bond pads 507. However, any suitable devices may be utilized.

In an embodiment the first semiconductor device 601 may be configured to work with the optical interposer 100 for a desired functionality. In some embodiments the first semiconductor device 601 may be a high bandwidth memory (HBM) module, an xPU, a logic die, a 3DIC die, a CPU, a GPU, a SoC die, a MEMS die, combinations of these, or the like. Any suitable device with any suitable functionality, may be used, and all such devices are fully intended to be included within the scope of the embodiments.

In an embodiment the first semiconductor device 601 and the first bonding layer 505 may be bonded using a dielectric-to-dielectric and metal-to-metal bonding process. In a particular embodiment which utilizes a dielectric-to-dielectric and metal-to-metal bonding process, the process may be initiated by activating the surfaces of the second bonding layer 609 and the surfaces of the first bonding layer 505. Activating the top surfaces of the first bonding layer 505 and the second bonding layer 609 may comprise a dry treatment, a wet treatment, a plasma treatment, exposure to an inert gas plasma, exposure to H₂, exposure to N₂, exposure to O₂, combinations thereof, or the like, as examples. In embodiments where a wet treatment is used, an RCA cleaning may be used, for example. In another embodiment, the activation process may comprise other types of treatments. The activation process assists in the bonding of the first bonding layer 505 and the second bonding layer 609.

After the activation process the optical interposer 100 and the first semiconductor device 601 may be cleaned using, e.g., a chemical rinse, and then the first semiconductor device 601 is aligned and placed into physical contact with the optical interposer 100. The optical interposer 100 and the first semiconductor device 601 are then subjected to thermal treatment and contact pressure to bond the optical interposer 100 and first semiconductor device 601. For example, the optical interposer 100 and the first semiconductor device 601 may be subjected to a pressure of about 200 kPa or less, and a temperature between about 25° C. and about 250° C. to fuse the optical interposer 100 and the first semiconductor device 601. The optical interposer 100 and the first semiconductor device 601 may then be subjected to a temperature at or above the eutectic point for material of the first bond pads 507 and the third bond pads 611, e.g., between about 150° C. and about 650° C., to fuse the metal. In this manner, the optical interposer 100 and the first semiconductor device 601 forms a dielectric-to-dielectric and metal-to-metal bonded device. In some embodiments, the bonded dies are subsequently baked, annealed, pressed, or otherwise treated to strengthen or finalize the bond.

Additionally, while specific processes have been described to initiate and strengthen the bonds, these descriptions are intended to be illustrative and are not intended to be limiting upon the embodiments. Rather, any suitable combination of baking, annealing, pressing, or combination of processes may be utilized. All such processes are fully intended to be included within the scope of the embodiments.

FIG. 6 additionally illustrates that, once the first semiconductor device 601 has been bonded, a first gap-fill material 613 is deposited in order to fill the space around the first semiconductor device 601 and provide additional support. In an embodiment the first gap-fill material 613 may be a material such as silicon oxide, silicon nitride, silicon oxynitride, combinations of these, or the like, deposited to fill and overfill the spaces around the first semiconductor device 601. However, any suitable material and method of deposition may be utilized.

Once the first gap-fill material 613 has been deposited, the first gap-fill material 613 may be planarized in order to expose the first semiconductor device 601. In an embodiment the planarization process may be a chemical mechanical planarization process, a grinding process, or the like. However, any suitable planarization process may be utilized.

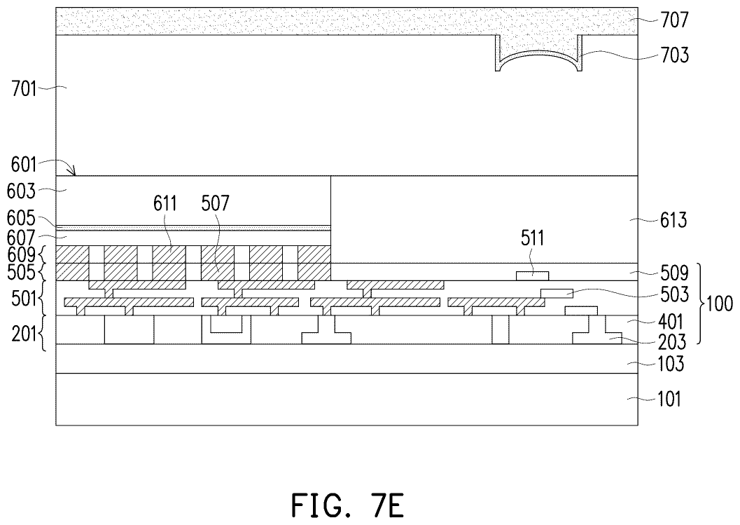

FIGS. 7A-7E illustrate a formation and attachment of a support substrate 701 to the first semiconductor device 601 and the first gap-fill material 613. Looking first at FIG. 7A, there is illustrated that, in an embodiment the support substrate 701 may be a support material that is transparent to the wavelength of light that is desired to be used, such as silicon. However, any suitable material may be utilized.

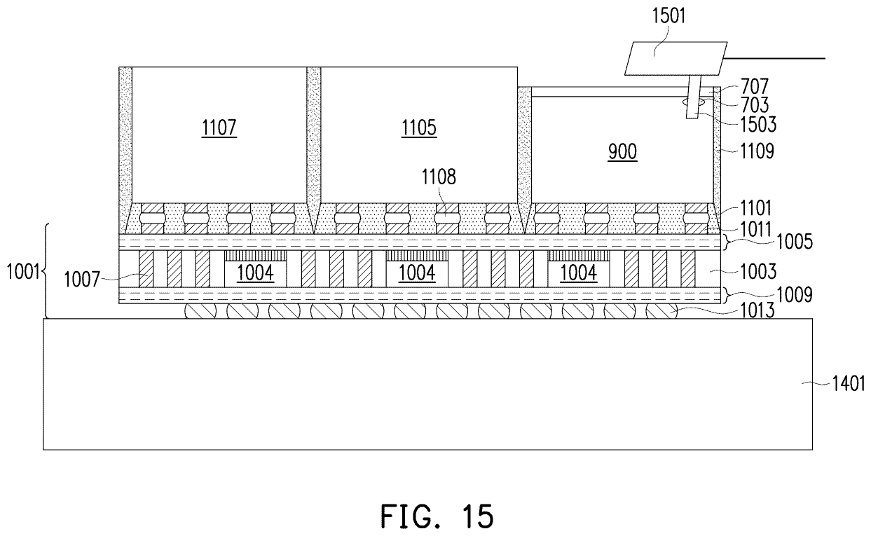

FIG. 7A additionally illustrates that the support substrate 701 may further comprise one or more first coupling lens 703 positioned to facilitate movement from a fiber array unit 1501 (not illustrated in FIG. 7A but illustrated and described further below with respect to FIG. 15). In an embodiment the first coupling lens 703 may be formed by shaping the material of the support substrate (e.g., silicon) using masking and etching processes. However, any suitable process may be utilized.

Additionally, if desired, a first anti-reflective coating (ARC) (not separately illustrated in FIG. 7A) may be formed on the first coupling lens 703. In an embodiment the first ARC may be one or more layers of materials which help to prevent undesired reflections as light is focused through the first coupling lens 703. In a particular embodiment the one or more layers of materials may be materials such as silicon oxide, silicon nitride, combinations of these, or the like, formed using processes such as chemical vapor deposition, atomic layer deposition, physical vapor deposition, oxidation, nitridation, combinations of these, or the like.

In a particular embodiment the first ARC may be formed using a first layer of silicon oxide and a first layer of silicon nitride formed over the first layer of silicon oxide. A second layer of silicon oxide and a second layer of silicon nitride are deposited over the first layer of silicon oxide and the first layer of silicon nitride, forming an alternating stack of silicon oxide and silicon nitride. Once all of the desired layers have been deposited, the layers may be patterned using, e.g., a photolithographic masking and etching process. However, any suitable combinations of materials and processes may be utilized.

Optionally, if the recess formed by the first coupling lens 703 is not otherwise filled, a fill material may be deposited in order to fill the recess formed by the first coupling lens 703. In an embodiment the fill material may be a cladding material such as silicon oxide deposited using a method such as chemical vapor deposition, physical vapor deposition, atomic layer deposition, combinations of these, or the like. Once the recess has been filled, the fill material may be planarized using a process such as chemical mechanical polishing in order to remove portions of the fill material outside of the recess.

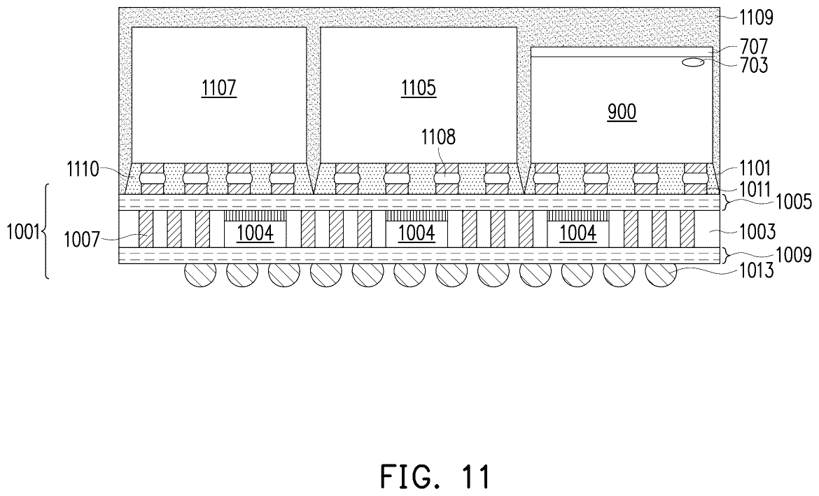

FIG. 7B illustrates formation of a protective layer 707 over the support substrate 701, the first coupling lens 703, the anti-reflective layer and, if the fill material is not present, within the recess formed by the formation of the first coupling lens 703. In an embodiment the protective layer 707 is utilized to provide an anti-reflective coating that also provides additional protection for the underlying structures during a removal of an encapsulant 1109 (not illustrated in FIG. 7B but illustrated and described below with respect to FIG. 11), and also to help ensure that the surface caused by the removal of the encapsulant 1109 remains smoother than otherwise. Keeping this surface smooth helps the transmission of the optical signals 1503 (not illustrated in FIG. 7B but illustrated in FIG. 15) between the fiber array unit 1501 and the first optical package 900.

In a particular embodiment the protective layer 707 may be formed of a protective material such as silicon oxide, although other suitable materials, such as silicon nitride, oxynitride, dielectric material including oxide, nitride, polyimide, photoresist, polymer material, or combinations of these, or the like, may alternatively be used. The protective material may be deposited using a deposition process such as chemical vapor deposition, physical vapor deposition, atomic layer deposition, combinations of these, or the like, to a thickness of between about 50 Å and about 3000 Å. However, any suitable materials, processes, or thicknesses may be utilized.

Optionally, once the protective layer 707 has been deposited, the protective layer 707 may be planarized to provide a planar, smooth surface. In an embodiment the protective layer 707 may be planarized using, e.g., a planarization process such as a chemical mechanical polishing process. However, any suitable planarization process may be utilized.

Of course, while the precise steps described above may be utilized to form the first coupling lens 703 and the protective layer 707, these precise steps are intended to be illustrative and are not intended to limit the embodiments. Rather, any suitable combination or order of steps may be utilized. For example, in some embodiments the fill material and the first ARC may be excluded and the material of the protective layer 707 may be used to fill the remainder of the recess used to form the first coupling lens 703. Any suitable combination of steps may be utilized, and all such modifications are fully intended to be included within the scope of the embodiments.

FIG. 7C illustrates one such modification for the protective layer 707. In the embodiment illustrated in FIG. 7C, the protective layer 707 is deposited in such a manner that the protective layer 707 is conformal to the underlying shape of the one or more first coupling lens 703. The shape of the protective layer 707 may be controlled by using a conformal deposition method such as chemical vapor deposition, atomic layer deposition, combinations of these, or the like. However, any suitable method may be utilized.

FIG. 7D illustrates yet another embodiment for the protective layer 707. In this embodiment the protective layer 707 is a multi-layer structure that comprises a bottom layer 711, a middle layer 713, and a top layer 715. In an embodiment the bottom layer 711 may be formed using similar materials and methods as described above with respect to the protective layer 707 in FIG. 7C, such as depositing a material such as silicon oxide that is conformal to the underlying shape. However, any suitable material and method may be utilized.

The middle layer 713 may be deposited over the bottom layer 711. In an embodiment the middle layer 713 may be a material such as silicon nitride, silicon oxide, combinations of these, or the like, deposited using a deposition process such as chemical vapor deposition, atomic layer deposition, physical vapor deposition, combinations of these, or the like. However, any suitable material and method of deposition may be utilized.

The top layer 715 may be deposited over the middle layer 713. In an embodiment the top layer 715 may be formed using similar materials and methods as described above with respect to the protective layer 707 in FIG. 7B, such as depositing a material such as silicon oxide that is blanket deposited and then planarized. However, any suitable material and method may be utilized.

FIG. 7E illustrates that, once the protective layer 707 has been formed (using any of the embodiments described above with respect to FIGS. 7A-7D), the support substrate 701 may be attached to the first semiconductor device 601 and the first gap-fill material 613. In an embodiment the support substrate 701 may be attached using, e.g., an adhesive (not separately illustrated in FIG. 7E). However, in other embodiments the support substrate 701 may be bonded to the first semiconductor device 601 and the first gap-fill material 613 using, e.g., a bonding process such as a fusion bonding process. Any suitable method of attaching the support substrate 701 may be used.

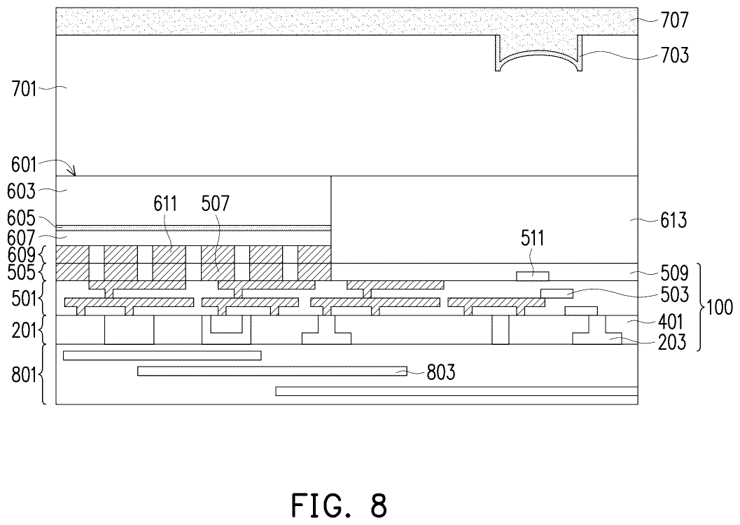

FIG. 8 illustrates a removal of the first substrate 101 and, optionally, the first insulator layer 103, thereby exposing the first active layer 201 of first optical components 203. In an embodiment the first substrate 101 and the first insulator layer 103 may be removed using a planarization process, such as a chemical mechanical polishing process, a grinding process, one or more etching processes, combinations of these, or the like. However, any suitable method may be used in order to remove the first substrate 101 and/or the first insulator layer 103.

Once the first substrate 101 and the first insulator layer 103 have been removed, a second active layer 801 of fourth optical components 803 may be formed on a back side of the first active layer 201. In an embodiment the second active layer 801 of fourth optical components 803 may be formed using similar materials and similar processes as the second optical components 503 of the first metallization layers 501 (described above with respect to FIG. 5). For example, the second active layer 801 of fourth optical components 803 may be formed of alternating layers of a cladding material such as silicon oxide and core material such as silicon nitride formed using deposition and patterning processes in order to form optical components such as waveguides and the like.

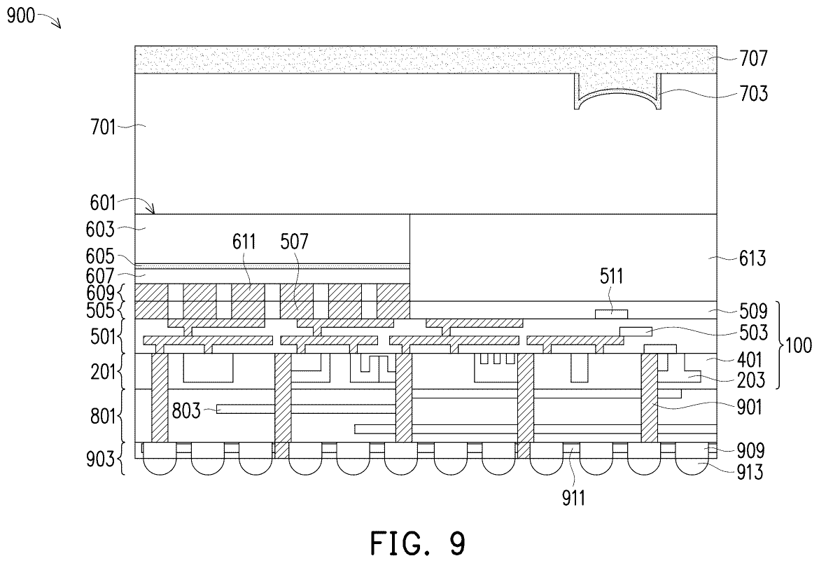

FIG. 9 illustrates formation of first through device vias (TDVs) 901 and formation of a third bonding layer 903 to form a first optical package 900 which, in some embodiments is a photonic engine. In an embodiment the first through device vias 901 extend through the second active layer 801 and the first active layer 201 so as to provide a quick passage of power, data, and ground through the optical interposer 100. In an embodiment the first through device vias 901 may be formed by initially forming through device via openings into the optical interposer 100. The through device via openings may be formed by applying and developing a suitable photoresist (not shown), and removing portions of the second active layer 801 and the optical interposer 100 that are exposed.

Once the through device via openings have been formed within the optical interposer 100, the through device via openings may be lined with a liner. The liner may be, e.g., an oxide formed from tetraethylorthosilicate (TEOS) or silicon nitride, although any suitable dielectric material may alternatively be used. The liner may be formed using a plasma enhanced chemical vapor deposition (PECVD) process, although other suitable processes, such as physical vapor deposition or a thermal process, may also be used.

Once the liner has been formed along the sidewalls and bottom of the through device via openings, a barrier layer (also not independently illustrated) may be formed and the remainder of the through device via openings may be filled with first conductive material. The first conductive material may comprise copper, although other suitable materials such as aluminum, alloys, doped polysilicon, combinations thereof, and the like, may be utilized. The first conductive material may be formed by electroplating copper onto a seed layer (not shown), filling and overfilling the through device via openings. Once the through device via openings have been filled, excess liner, barrier layer, seed layer, and first conductive material outside of the through device via openings may be removed through a planarization process such as chemical mechanical polishing (CMP), although any suitable removal process may be used.

Optionally, in some embodiments once the first through device vias 901 have been formed, second metallization layers (not separately illustrated in FIG. 9) may be formed in electrical connection with the first through device vias 901. In an embodiment the second metallization layers may be formed as described above with respect to the first metallization layers 501, such as being alternating layers of dielectric and conductive materials using damascene processes, dual damascene process, or the like. In other embodiments, the second metallization layers may be formed using a plating process to form and shape conductive material, and then cover the conductive material with a dielectric material. However, any suitable structures and methods of manufacture may be utilized.

The third bonding layer 903 is formed in order to provide electrical connections between the optical interposer 100 and subsequently attached devices. In an embodiment the third bonding layer 903 may be similar to the first bonding layer 505, such as having third bond pads 909 (similar to the first bond pads 507) and even fifth optical components 911 (similar to the third optical components 511). However, any suitable devices may be utilized.

FIG. 9 additionally illustrates a placement of first external connectors 913 which may be formed to provide conductive regions for contact between the third bond pads 909 to other external devices. The first external connectors 913 may be conductive bumps (e.g., C4 bumps, ball grid arrays, microbumps, etc.) or conductive pillars utilizing materials such as solder and copper. In an embodiment in which the first external connectors 913 are contact bumps, the first external connectors 913 may comprise a material such as tin, or other suitable materials, such as silver, lead-free tin, or copper. In an embodiment in which the first external connectors 913 are tin solder bumps, the first external connectors 913 may be formed by initially forming a layer of tin through such commonly used methods such as evaporation, electroplating, printing, solder transfer, ball placement, etc. Once a layer of tin has been formed on the structure, a reflow may be performed in order to shape the material into the desired bump shape.

Of course, while the use of first external connectors 913 is one embodiment which may be used in order to provide connections for the first optical package 900, this is intended to be illustrative and is not intended to limit the embodiments. Rather, any suitable method of physically, electrically, and in some cases optically connecting the first optical package 900, such as dielectric-to-dielectric and metal-to-metal bonding, may also be utilized. Any suitable method of bonding the first optical package 900 may be used.

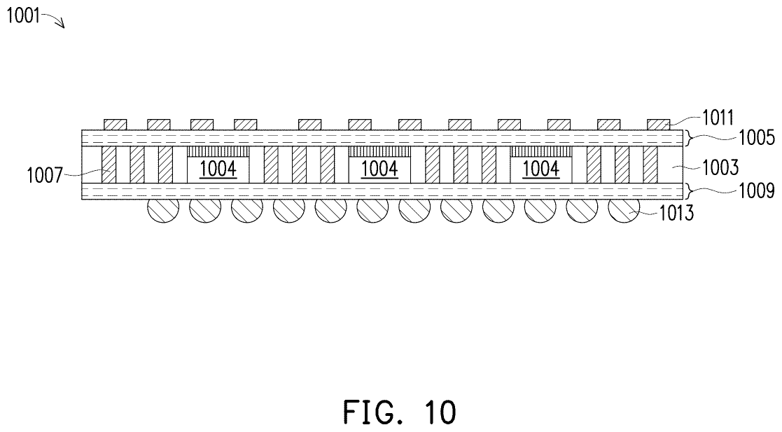

FIG. 10 illustrates an interposer substrate 1001 that is used to couple the first optical package 900 with other devices to form, for example, a chip-on-wafer-on-substrate device. In an embodiment the interposer substrate 1001 comprises a semiconductor substrate 1003, third metallization layers 1005, third through device vias (TDVs) 1007, fourth metallization layers 1009, and second external connectors 1013. The semiconductor substrate 1003 may comprise bulk silicon, doped or undoped, or an active layer of a silicon-on-insulator (SOI) substrate. Generally, an SOI substrate comprises a layer of a semiconductor material such as silicon, germanium, silicon germanium, silicon germanium on insulator (SGOI), or combinations thereof. Other substrates that may be used include multi-layered substrates, gradient substrates, or hybrid orientation substrates.

Optionally, first active devices (not separately illustrated) may be added to the semiconductor substrate 1003. The first active devices comprise a wide variety of active devices and passive devices such as capacitors, resistors, inductors and the like that may be used to generate the desired structural and functional requirements of the design for the semiconductor substrate 1003. The first active devices may be formed using any suitable methods either within or else on the semiconductor substrate 1003.

Openings may be formed within the semiconductor substrate 1003 in order to receive first bridge dies 1004, wherein the openings may be formed using, e.g., one or more photolithographic masking and etching processes. In an embodiment the first bridge dies 1004 may be local silicon interconnect (LSI) dies, which are used to bridge and electrically connect subsequently placed devices, and may be placed using, e.g., a pick and place process. However, any suitable devices and methods may be utilized.

The third metallization layers 1005 are formed over the semiconductor substrate 1003 of the interposer substrate 1001 and the first active devices and are designed to connect the various devices to form functional circuitry. In an embodiment the third metallization layers 1005 of the interposer substrate 1001 are formed of alternating layers of dielectric (e.g., low-k dielectric materials, extremely low-k dielectric material, ultra low-k dielectric materials, combinations of these, or the like) and conductive material and may be formed through any suitable process (such as deposition, damascene, dual damascene, etc.). However, any suitable materials and processes may be utilized.

Fourth bond pads 1011 may be formed on the third metallization layers 1005. In an embodiment the fourth bond pads 1011 may be formed using similar methods and materials as the third bond pads 909 discussed above with respect to FIG. 9. However, any suitable methods and materials may be utilized.

Additionally, at any desired point in the manufacturing process, the second TDVs 1007 may be formed within the semiconductor substrate 1003 and, if desired, one or more layers of the third metallization layers 1005, in order to provide electrical connectivity from a front side of the semiconductor substrate 1003 to a back side of the semiconductor substrate 1003. In an embodiment the second TDVs 1007 may be formed by initially forming through device via (TDV) openings into the semiconductor substrate 1003 and, if desired, any of the overlying third metallization layers 1005 (e.g., after the desired third metallization layer 1005 has been formed but prior to formation of the next overlying third metallization layer 1005). The TDV openings may be formed by applying and developing a suitable photoresist, and removing portions of the underlying materials that are exposed to a desired depth. The TDV openings may be formed so as to extend into the semiconductor substrate 1003 to a depth greater than the eventual desired height of the semiconductor substrate 1003.

Once the TDV openings have been formed within the semiconductor substrate 1003 and/or any third metallization layers 1005, the TDV openings may be lined with a liner. The liner may be, e.g., an oxide formed from tetraethylorthosilicate (TEOS) or silicon nitride, although any suitable dielectric material may be used. The liner may be formed using a plasma enhanced chemical vapor deposition (PECVD) process, although other suitable processes, such as physical vapor deposition or a thermal process, may be used.

Once the liner has been formed along the sidewalls and bottom of the TDV openings, a barrier layer may be formed and the remainder of the TDV openings may be filled with first conductive material. The first conductive material may comprise copper, although other suitable materials such as aluminum, alloys, doped polysilicon, combinations thereof, and the like, may be utilized. The first conductive material may be formed by electroplating copper onto a seed layer, filling and overfilling the TDV openings. Once the TDV openings have been filled, excess liner, barrier layer, seed layer, and first conductive material outside of the TDV openings may be removed through a planarization process such as chemical mechanical polishing (CMP), although any suitable removal process may be used.

Once the TDV openings have been filled, the semiconductor substrate 1003 may be thinned until the second TDVs 1007 have been exposed. In an embodiment the semiconductor substrate 1003 may be thinned using, e.g., a chemical mechanical polishing process, a grinding process, or the like. Further, once exposed, the second TDVs 1007 may be recessed using, e.g., one or more etching processes, such as a wet etch process in order to recess the semiconductor substrate 1003 so that the second TDVs 1007 extend out of the semiconductor substrate 1003.

Once the second TDVs 1007 have been formed, a fourth metallization layer 1009 may be formed on an opposite side of the semiconductor substrate 1003 from the third metallization layers 1005. The fourth metallization layer 1009 may be formed using similar methods and materials as the third metallization layers 1005. However, any suitable methods may be utilized.

In an embodiment the second external connectors 1013 may be placed and may be, e.g., a ball grid array (BGA) which comprises a eutectic material such as solder, although any suitable materials may be used. Optionally, an underbump metallization or additional metallization layers may be utilized between the fourth metallization layers 1009 and the second external connectors 1013. In an embodiment in which the second external connectors 1013 are solder bumps, the second external connectors 1013 may be formed using a ball drop method, such as a direct ball drop process. In another embodiment, the solder bumps may be formed by initially forming a layer of tin through any suitable method such as evaporation, electroplating, printing, solder transfer, and then performing a reflow in order to shape the material into the desired bump shape. Once the second external connectors 1013 have been formed, a test may be performed to ensure that the structure is suitable for further processing.

Of course, while the above described process in one method by which the interposer substrate 1001 may be formed, this description is intended to be illustrative and is not intended to limit the embodiments. Rather, any suitable method of forming the interposer substrate 1001 may be utilized. For example, in another embodiment, the second TDVs 1007 may be formed first and the first bridge dies 1004 may be placed and the encapsulated with an encapsulant (instead of the semiconductor substrate 1003), and then the metallization layers may be formed. Any suitable process and devices may be utilized and all such processes are fully intended to be included within the scope of the embodiments.

FIG. 11 illustrates that, once the interposer substrate 1001 has been formed, the first optical package 900 (shown in FIG. 11 in a very simplified form for clarity) may be attached to the interposer substrate 1001. In an embodiment the first optical package 900 may be attached to the interposer substrate 1001 by aligning the first external connectors 913 with the fourth bond pads 1011 of the interposer substrate 1001. Once aligned and in physical contact, the first external connectors 913 are reflowed by raising the temperature of the first external connectors 913 past a eutectic point of the first external connectors 913, thereby shifting the material of the first external connectors 913 to a liquid phase. Once reflowed, the temperature is reduced in order to shift the material of the first external connectors 913 back to a solid phase, thereby bonding the first optical package 900 to the interposer substrate 1001.

Optionally, a first underfill material 1101 may be placed. The first underfill material may reduce stress and protect the joints resulting from the reflowing of the first external connectors 913. The first underfill material may be formed by a capillary flow process after the first optical package 900 has been attached.

FIG. 11 additionally illustrates a bonding of a second semiconductor device 1105 and a third semiconductor device 1107 onto the interposer substrate 1001. In some embodiments, the second semiconductor device 1105 and the third semiconductor device 1107 are electronic integrated circuits (EIC) such as ASIC devices. In a particular embodiment the second semiconductor device 1105 and the third semiconductor device 1107 comprise a system on chip device and a high bandwidth memory device. Of course, while the second semiconductor device 1105 and the third semiconductor device 1107 are SOC and HBM devices in one embodiment, the embodiments are not restricted to the second semiconductor device 1105 and the third semiconductor device 1107 being SOC and HBM devices. Rather, the second semiconductor device 1105 and the third semiconductor device 1107 may be any suitable semiconductor devices, such as a processor die, a memory die, or other type of functional die. In particular embodiments the second semiconductor device 1105 may be a logic die, a 3DIC die, a CPU, a GPU, a MEMS die, a XPU die, combinations of these, or the like. Any suitable device with any suitable functionality, may be used, and all such devices are fully intended to be included within the scope of the embodiments.

In an embodiment the second semiconductor device 1105 and the third semiconductor device 1107 may be bonded to the interposer substrate 1001 using, e.g., third external connections 1108. The third external connections 1108 may be conductive bumps (e.g., ball grid arrays, microbumps, etc.) or conductive pillars utilizing materials such as solder and copper. In an embodiment in which the third external connections 1108 are contact bumps, the third external connections 1108 may comprise a material such as tin, or other suitable materials, such as silver, lead-free tin, or copper. In an embodiment in which the third external connections 1108 are tin solder bumps, the third external connections 1108 may be formed by initially forming a layer of tin through such commonly used methods such as evaporation, electroplating, printing, solder transfer, ball placement, etc. Once a layer of tin has been formed on the structure, a reflow may be performed in order to shape the material into the desired bump shape.

Additionally, once the third external connections 1108 have been placed, the second semiconductor device 1105 and the third semiconductor device 1107 are aligned with the interposer substrate 1001. Once aligned and in physical contact, the third external connections 1108 are reflowed by raising the temperature of the third external connections 1108 past a eutectic point of the third external connections 1108, thereby shifting the material of the third external connections 1108 to a liquid phase. Once reflowed, the temperature is reduced in order to shift the material of the third external connections 1108 back to a solid phase, thereby bonding the second semiconductor device 1105 and the third semiconductor device 1107 to the interposer substrate 1001.

Optionally, a second underfill material 1110 may be placed. The second underfill material 1110 may reduce stress and protect the joints resulting from the reflowing of the third external connections 1108. The second underfill material 1110 may be formed by a capillary flow process after the second semiconductor device 1105 and the third semiconductor device 1107 have been attached.

Once the second semiconductor device 1105, the third semiconductor device 1107, and the first optical package 900 have been bonded to the interposer substrate 1001, the second semiconductor device 1105, the third semiconductor device 1107, and the first optical package 900 are encapsulated with an encapsulant 1109. In an embodiment the encapsulant 1109 may be a material such as a molding compound placed using an injection molding process. Once in place, the molding compound may be cured. However, any suitable material and process may be used.

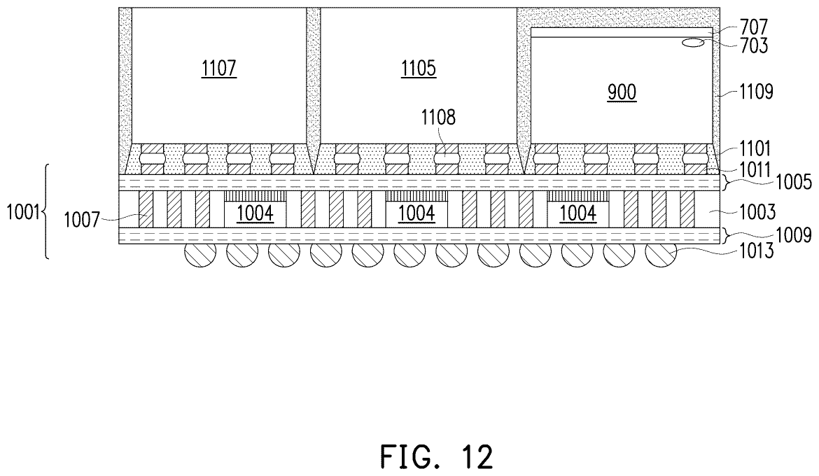

FIG. 12 illustrates that, once the encapsulant 1109 has been placed and cured, the encapsulant 1109 may be planarized. In an embodiment the encapsulant 1109 may be planarized using a planarization process such as a chemical mechanical polishing process until the encapsulant 1109 is planar with one or both of the second semiconductor device 1105 and the third semiconductor device 1107. However, any suitable planarization process may be utilized.

Additionally, given the damage that can occur during the planarization process, it is advantageous to keep the planarization process away from the first optical package 900. As such, in order to prevent the planarization process for the encapsulant 1109 from being damage, the height of the second semiconductor device 1105 and/or the third semiconductor device 1107 is deliberately made higher than the height of the first optical package 900. As such, the encapsulant 1109 remains over the first optical package 900 after the encapsulant 1109 is planarized.

However, because the first optical package 900 has a different height from at least one of the second semiconductor device 1105 and the third semiconductor device 1107, the planarization process that exposes the second semiconductor device 1105 and/or the third semiconductor device 1107 will not necessarily expose the first optical package 900. As such, once the encapsulant 1109 has been planarized, a portion of the encapsulant 1109 may remain in place over the first optical package 900.

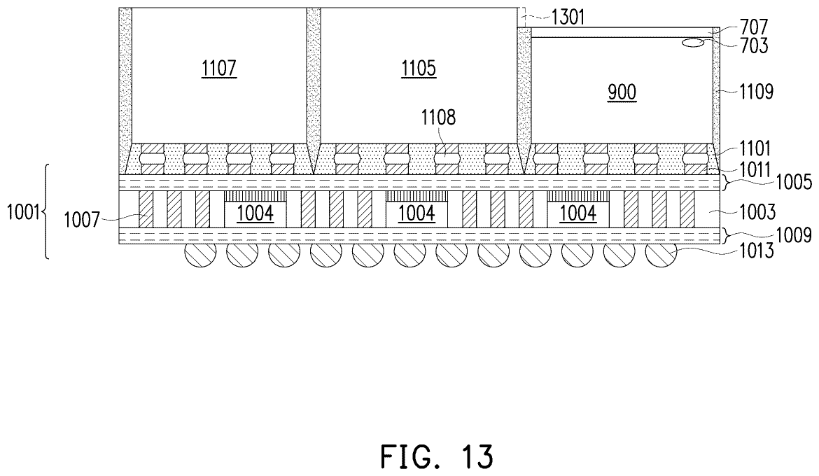

FIG. 13 illustrates a removal of the encapsulant 1109 from over the first optical package 900 in order to assist the transmission of optical signals 1503 to the first optical package 900. In an embodiment the encapsulant 1109 may be removed using one or more photolithographic masking and etching processes, such as a dry etching process or a wet etching process. For example, a photoresist may be placed and patterned over the encapsulant 1109, and the one or more directional etching processes such as a reactive ion etching process may be utilized using the photoresist as a mask to remove the encapsulant 1109 over the first optical package 900. However, any suitable methods may be utilized.

In an embodiment the encapsulant 1109 may be removed from over the first optical package 900 and also remove all the encapsulant 1109 from a sidewall of the second semiconductor device 1105. In other embodiments the encapsulant 1109 may be removed from over the first optical package 900 while leaving the encapsulant 1109 along all of the sidewalls of the second semiconductor device 1105 and the third semiconductor device 1107 (illustrated in FIG. 13 by the dashed line labeled 1301). Any suitable pattern may be utilized.

However, because the protective layer 707 is present, the protective layer 707 is more resistant to damage from the removal of the encapsulant 1109. Less damage allows for a higher transmission of the optical signal 1503 that will transit through the protective layer 707. Additionally, this solution to reducing the damage is realistically achievable for a photonic engine in an Co-Packaged Optics (CPO) system. Such solutions are also highly compatible with the current baseline flows for manufacture.

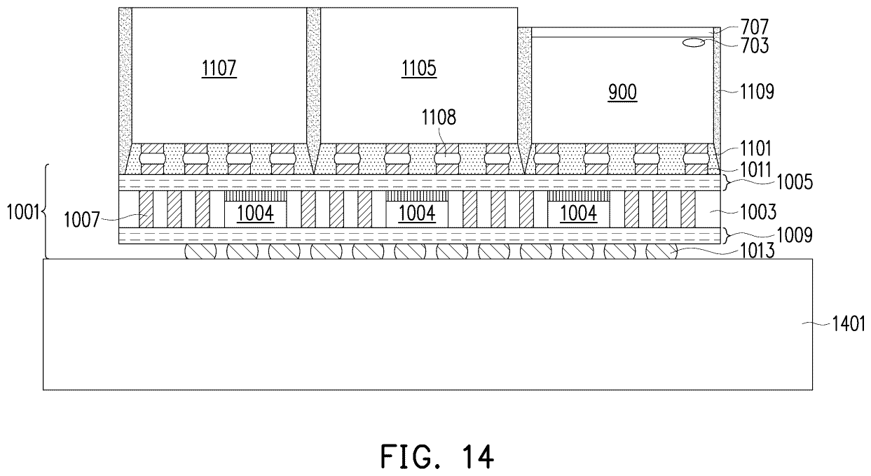

FIG. 14 illustrates that, once the second semiconductor device 1105, the third semiconductor device 1107, and the first optical package 900 have been bonded to the interposer substrate 1001, the interposer substrate 1001 may be bonded to a second substrate 1401 with, e.g., the second external connectors 1013. In an embodiment the second substrate 1401 may be a package substrate, which may be a printed circuit board (PCB) or the like. The second substrate 1401 may include one or more dielectric layers and electrically conductive features, such as conductive lines and vias. In some embodiments, the second substrate 1401 may include through-vias, active devices, passive devices, and the like. The second substrate 1401 may further include conductive pads formed at the upper and lower surfaces of the second substrate 1401.

The second external connectors 1013 may be aligned with corresponding conductive connections on the second substrate 1401. Once aligned the second external connectors 1013 may then be reflowed in order to bond the second substrate 1401 to the interposer substrate 1001. However, any suitable bonding process may be used to connect the interposer substrate 1001 to the second substrate 1401.

Additionally, the second substrate 1401 may be prepared for further connections by placing external connections (not separately illustrated) on an opposite side of the second substrate 1401 from the interposer substrate 1001. In an embodiment the external connections may be formed using similar processes and materials as the second external connectors 1013. However, any suitable materials and processes may be utilized.

FIG. 15 illustrates a placement of a fiber array unit (FAU) 1501 over the first optical package 900. In an embodiment the fiber array unit 1501 provides an ingress and egress to optical signals 1503. In an embodiment the fiber array unit assembly 1501 receives optical fibers (not separately illustrated in FIG. 15), arranges the optical fibers with a fiber sheath, and directs optical signals 1503 from the optical fibers towards the first optical package 900. Support materials such as glass portions and/or a silicon substrate support the various components of the fiber array unit 1501 and may be held together with an index matching gel.

By utilizing the protective layer 707 as discussed above, the protective layer 707 protects the top surface of the underlying device, helping to allow a high transmission of the optical signal 1503. Additionally, this solution is realistically achievable for a photonic engine in an Co-Packaged Optics (CPO) system. Such solutions are also highly compatible with the current baseline flows for manufacture.

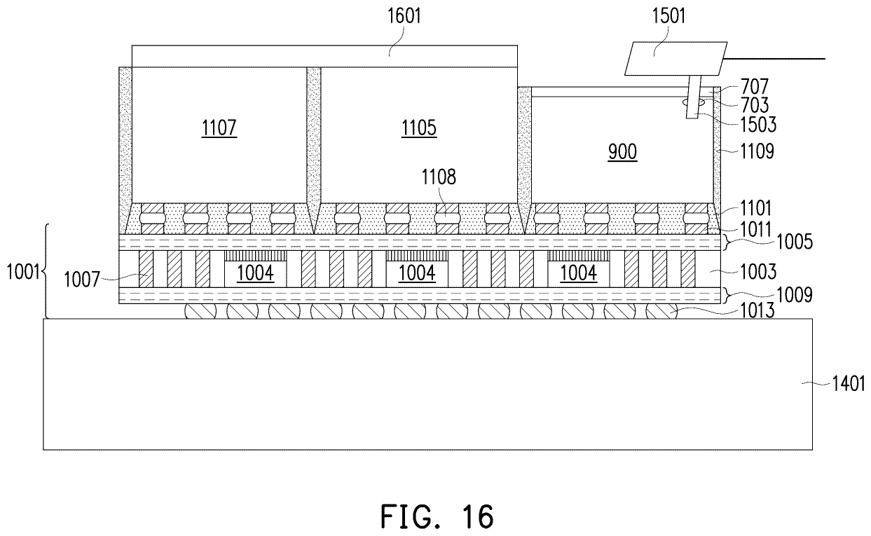

FIG. 16 illustrates another embodiment in which a heat sink 1601 may be utilized in order to help remove heat from the second semiconductor device 1105 and/or the third semiconductor device 1107. In an embodiment the heat sink 1601 may be formed using materials exhibiting high thermal conductivity such as aluminum, copper, other metals, alloys, combinations thereof, and the like, and aids in the cooling of the other devices by increasing a given surface area to be exposed to a cooling agent surrounding it such as air. The heat transfer mechanisms occur through the convection of the surrounding air, the conduction through the air, and radiation. For example, the heat sink 1601 may exhibit a much greater surface area for convection by employing a large number of fins in the form of a matrix of geometrically shaped pins or an array of straight or flared fins. In another example, such as where convection is low, a matted-black surface color may radiate much more efficiently than shiny, metallic colors in the visible spectrum. Any suitable form for the heat sink may be utilized.

FIG. 16 additionally illustrated another embodiment of the removal of the encapsulant 1109 from over the first optical package 900. In this embodiment, only the encapsulant 1109 which is directly over the first optical package 900 is removed, while the encapsulant 1109 that is laterally removed from the first optical package 900 is left in place. However, any suitable patterning of the encapsulant 1109 may be utilized.

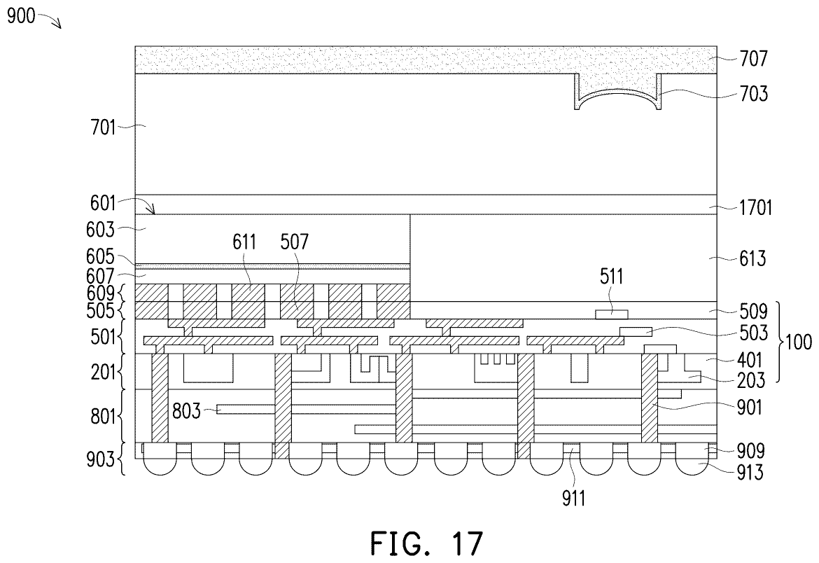

FIG. 17 illustrates yet another embodiment which utilizes a second anti-reflective coating 1701 located between the support substrate 701 and the first semiconductor device 601. In an embodiment the second anti-reflective coating 1701 may be a single layer or multi-layer structure similar to the protective layer 707 and may be formed using similar materials and methods as described above with respect to FIGS. 7A-7D. Additionally, the second anti-reflective coating 1701 may be formed on either the support substrate 701 or the first semiconductor device 601. However, any suitable materials and methods may be utilized.

In an embodiment, a method of manufacturing an optical device includes: forming a protective layer over a support substrate, a first semiconductor die, and an optical interposer; encapsulating the optical interposer with a second semiconductor die with an encapsulant; planarizing the encapsulant with the second semiconductor die; and removing the encapsulant to expose the protective layer after the planarizing the encapsulant. In an embodiment the forming the protective layer forms silicon oxide. In an embodiment the method further includes attaching the optical interposer to an interposer substrate prior to the encapsulating. In an embodiment the method further includes attaching the second semiconductor die to the interposer substrate prior to the encapsulating. In an embodiment the forming the protective layer forms at least a portion of the protective layer conformally. In an embodiment the forming the protective layer forms a multi-layer structure. In an embodiment the method further includes planarizing the encapsulant with the second semiconductor die.

In another embodiment, a method of manufacturing an optical device includes: bonding a first optical package to an interposer substrate, the first optical package comprising a protective layer over a support substrate, the support substrate over a first semiconductor die, the first semiconductor die being bonded to an optical interposer; bonding a second semiconductor die to the interposer substrate; encapsulating the second semiconductor die and the first optical package with an encapsulant; and removing a portion of the encapsulant to expose at least a portion of the protective layer. In an embodiment after the removing the portion of the encapsulant a sidewall of the second semiconductor die is exposed. In an embodiment after the removing the portion of the encapsulant each sidewall of the second semiconductor die remains covered by the encapsulant. In an embodiment the protective layer comprises silicon oxide. In an embodiment the protective layer is a conformal with a coupling lens within the support substrate. In an embodiment the protective layer comprises multiple layers of different materials. In an embodiment there is an anti-reflective layer on an opposite side of the support substrate from the protective layer.

In yet another embodiment an optical device includes: a first optical package bonded to an interposer substrate; a first semiconductor die bonded to the interposer substrate; an encapsulant surrounding the first semiconductor die and the first optical package; and a protective layer overlying the first optical package and exposed by the encapsulant. In an embodiment the protective layer comprises silicon oxide. In an embodiment the protective layer comprises multiple layers of different materials. In an embodiment the protective layer is conformal with an underlying lens. In an embodiment the encapsulant has a step change in height between the first semiconductor die and the first optical package. In an embodiment at least a part of a sidewall of the first semiconductor die is exposed by the encapsulant.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An optical device comprising:
an optical interposer bonded to a substrate;
a first semiconductor die bonded to the substrate, the first semiconductor die extending away from the substrate a different distance than the optical interposer;
an encapsulant encapsulating the optical interposer and the first semiconductor die, a first portion of the encapsulant being planar with the first semiconductor die; and
a protective layer located over the optical interposer, wherein the protective layer is planar with a second portion of the encapsulant.

2. The optical device of claim 1, wherein the protective layer comprises silicon oxide.

3. The optical device of claim 1, wherein the protective layer is conformal to an underlying lens.

4. The optical device of claim 1, wherein the protective layer is a multi-layer structure.

5. The optical device of claim 4, wherein the multi-layer structure comprises:
a bottom layer of silicon oxide;
a middle layer of silicon nitride; and
a top layer of silicon oxide.

6. The optical device of claim 1, further comprising a heat sink located over the first semiconductor die.

7. The optical device of claim 1, further comprising a fiber array unit attached to the protective layer.

8. An optical device comprising:
a first optical package bonded to an interposer substrate, the first optical package comprising a protective layer over a support substrate, the support substrate over a first semiconductor die, the first semiconductor die being bonded to an optical interposer;
a second semiconductor die bonded to the interposer substrate; and
an encapsulant encapsulating the second semiconductor die and the first optical package, the encapsulant having multiple heights from the interposer substrate and exposing at least a portion of the protective layer.

9. The optical device of claim 8, wherein the encapsulant exposes a sidewall of the second semiconductor die.

10. The optical device of claim 8, wherein each sidewall of the second semiconductor die is covered by the encapsulant.

11. The optical device of claim 8, wherein the protective layer comprises silicon oxide.

12. The optical device of claim 8, wherein the protective layer is conformal with a coupling lens within the support substrate.

13. The optical device of claim 8, wherein the protective layer comprises multiple layers of different materials.

14. The optical device of claim 13, further comprising a fiber array unit attached to the protective layer.

15. An optical device comprising:
an interposer substrate;
a first optical package bonded to the interposer substrate;
a first semiconductor die bonded to the interposer substrate, the first semiconductor die having a different height than the first optical package;
an encapsulant surrounding the first semiconductor die and the first optical package; and
a protective layer overlying the first optical package and exposed by the encapsulant.

16. The optical device of claim 15, wherein the protective layer comprises silicon oxide.

17. The optical device of claim 15, wherein the protective layer comprises multiple layers of different materials.

18. The optical device of claim 15, wherein the protective layer is conformal with an underlying lens.

19. The optical device of claim 15, wherein the encapsulant has a step change in height between the first semiconductor die and the first optical package.

20. The optical device of claim 15, wherein at least a part of a sidewall of the first semiconductor die is exposed by the encapsulant.
